(19) United States
(12) Patent Application Publication
(10) Pub. No.: US 2026/0076070 A1
(43) Pub. Date: Mar. 12, 2026

(54) DISPLAY DEVICE AND METHOD OF MANUFACTURING THE SAME

(71) Applicant: Samsung Display Co., Ltd., YONGIN-SI (KR)

(72) Inventors: JONGSUK LEE, Yongin-si (KR); KWAN BAE KONG, Yongin-si (KR); JIHOON SONG, Yongin-si (KR); JAE-YOUNG YU, Yongin-si (KR); YONGHWAN YOON, Yongin-si (KR)

(21) Appl. No.: 19/215,550

(22) Filed: May 22, 2025

(30) Foreign Application Priority Data
Sep. 6, 2024 (KR) 10-2024-0121399

(51) Int. Cl. H10K 59/80; H10K 59/12

(52) U.S. Cl. CPC H10K 59/873; H10K 59/1201

(57) ABSTRACT

A display device includes: a display panel including a display area, a pad area and a bending area, wherein the pad area is located adjacent to a first side of the display area, and the bending area is disposed between the display area and the pad area; a protective film attached to a lower surface of the display panel and including a protective film base and a first adhesive layer; and a cover layer located below the protective film, wherein the pad area is positioned on the cover layer in an overlapping arrangement with the display area due to bending of the bending area, and the protective film has a thickness of about 100 μm to about 130 μm, and a thickness of the first adhesive layer is about 10% to about 20% of a thickness of the protective film base.

### CROSS-REFERENCE TO RELATED APPLICATION

This application claims priority under 35 USC § 119 to Korean Patent Application No. 10-2024-0121399, filed on Sep. 6, 2024, in the Korean Intellectual Property Office, the disclosure of which is incorporated by reference herein in its entirety.

### TECHNICAL FIELD

Embodiments of the present invention relate to a display device and a method of manufacturing the same.

### DISCUSSION OF THE RELATED ART

With the continuous advancement of display technology, the demand for high-performance display devices has been steadily increasing. Modern display devices are expected to accommodate a wide range of applications, from consumer electronics to commercial and industrial uses. To meet these demands, display devices are becoming increasingly larger and thinner, and the desire for display devices that provide larger and thinner display devices while also providing accurate and vivid colors is also increasing.

### SUMMARY

According to an embodiment of the present invention, a display device includes: a display panel including a display area, a pad area and a bending area, wherein the pad area is located adjacent to a first side of the display area, and the bending area is disposed between the display area and the pad area; a protective film attached to a lower surface of the display panel and including a protective film base and a first adhesive layer; and a cover layer located below the protective film, wherein the pad area is positioned on the cover layer in an overlapping arrangement with the display area due to bending of the bending area, and the protective film has a thickness of about 100 μm to about 130 μm, and a thickness of the first adhesive layer is about 10% to about 20% of a thickness of the protective film base.

In an embodiment of the present invention, the display area includes a first display area, second display areas, and third display areas, wherein the first display area is a flat area, wherein the second display areas are located at edges of the first display area, and the third display areas are located between the second display areas, and the second display areas each have a single-curved surface shape, and the third display areas each have a double-curved surface shape.

In an embodiment of the present invention, the protective film overlaps with at least one of the first display area, the second display areas, or the third display areas.

In an embodiment of the present invention, the pad area is positioned directly on the cover layer.

In an embodiment of the present invention, the bending area has a radius of curvature between 0.1 mm to 0.4 mm.

In an embodiment of the present invention, the display device further includes: a spacer disposed between the pad area of the display panel and the cover layer, wherein a thickness of the spacer is smaller than the thickness of the protective film.

In an embodiment of the present invention, the spacer includes a second adhesive layer and a spacer base, and a thickness of the spacer base is about 60% or less of the thickness of the protective film base.

In an embodiment of the present invention, the cover layer includes at least one of a cushion layer or a metal plate.

In an embodiment of the present invention, the metal plate includes a material having an elastic modulus of 60 GPa or more at a temperature of about 68° F. to about 77° F.

In an embodiment of the present invention, the display panel includes an organic light-emitting diode.

According to an embodiment of the present invention, a method of manufacturing a display device includes: preparing a display panel including a display area, a pad area, and a bending area that is disposed between the display area and the pad area; preparing a protective film member, in which a protective film and a dummy protective film are formed on a carrier film having a same shape as the display panel; attaching the protective film and the dummy protective film to the display panel; removing the carrier film from the protective film member; removing the dummy protective film from the display panel; and bending the display panel in the bending area so that the pad area overlaps the display area, wherein the dummy protective film is formed at a position corresponding to the pad area and is exposed to light to facilitate removal of the dummy protective film from the display panel.

In an embodiment of the present invention, the protective film and the dummy protective film have a same thickness as each other, the protective film includes a protective film base and a first adhesive layer sequentially laminated on the carrier film, the dummy protective film includes a dummy protective film base and a dummy adhesive layer sequentially laminated on the carrier film, and the dummy adhesive layer further includes a photoinitiator.

In an embodiment of the present invention, the dummy adhesive layer includes the photoinitiator in an amount of at least 0.1 wt % and not more than 5 wt %.

In an embodiment of the present invention, in preparing the protective film member, the protective film is removed from an area corresponding to the bending area.

In an embodiment of the present invention, in preparing the protective film member, a spacer is formed on the dummy adhesive layer, wherein the spacer includes a spacer base and a second adhesive layer.

In an embodiment of the present invention, a sum of a thickness of the dummy protective film and a thickness of the spacer is equal to a thickness of the protective film, and a thickness of the spacer base is formed to be about 60% or less of a thickness of the protective film base.

In an embodiment of the present invention, the dummy protective film is separated from the spacer upon exposure to light.

In an embodiment of the present invention, the protective film has a thickness of about 100 μm to about 130 μm, wherein the protective film includes a protective film base and a first adhesive layer, and a thickness of the first adhesive layer is formed to be about 10% to about 20% of a thickness of the protective film base.

In an embodiment of the present invention, the display area includes a first display area, second display areas, and third display areas, wherein the first display area is a flat area, wherein the second display areas are located at edges of the first display area, and the third display areas are located between the second display areas, and the second display areas have a single-curved surface shape and the third display areas have a double-curved surface shape.

According to an embodiment of the present invention, an electronic device includes: a display device; a processor; a memory having stored application programs for execution by the processor, wherein the display device includes: a display panel including a display area, a pad area, and a bending area, wherein the pad area is located adjacent to a first side of the display area, and the bending area is disposed between the display area and the pad area; a protective film attached to a lower surface of the display panel and including a protective film base and an adhesive layer; and a cover layer located below the protective film, wherein the pad area is positioned on the cover layer in an overlapping arrangement with the display area due to bending of the bending area, and the protective film has a thickness of about 100 μm to about 130 μm, and a thickness of the adhesive layer is about 10% to about 20% of a thickness of the protective film base; and a user interface configured to sense user input via touch or cursor select of an icon presented on the display panel, wherein the processor is caused to execute one or more of the stored application programs upon receipt of the user input.

### BRIEF DESCRIPTION OF THE DRAWINGS

The above and other aspects, and features of embodiments of the present invention will be more apparent by describing in detail embodiments thereof, with reference to the accompanying drawings, in which:

FIG. 1 is a plan view schematically illustrating an example of a display device according to an embodiment of the present invention;

FIG. 2 is a perspective view schematically illustrating an example of a manufacturing process of the display device of FIG. 1;

FIG. 3 is a cross-sectional view schematically illustrating an example of the cross-section A-A′ of FIG. 1;

FIG. 4 is a circuit diagram illustrating an example of an equivalent circuit of one (sub)pixel of the display device of FIG. 1;

FIG. 5 is a cross-sectional view schematically illustrating an example of the cross-section B-B′ of FIG. 2;

FIGS. 6 and 7 are diagrams each illustrating a corner display area of FIG. 2;

FIG. 8 is a cross-sectional view schematically illustrating an example of the cross-section C-C′ of FIG. 2;

FIGS. 9 and 10 are cross-sectional views schematically illustrating a manufacturing process of a display device according to FIG. 8;

FIG. 11 is a cross-sectional view schematically illustrating an example of the cross-section C-C′ of FIG. 2; and

FIGS. 12 and 13 are cross-sectional views schematically illustrating a manufacturing process of a display device according to FIG. 11.

FIG. 14 is a block diagram of an electronic device according to an embodiment of the present invention.

FIG. 15 illustrates schematic views of individual electronic devices according to various embodiments of the present invention.

FIG. 16 is a diagram illustrating an electronic device according to an embodiment of the present invention.

### DETAILED DESCRIPTION OF THE EMBODIMENTS

Embodiments of the present invention will now be described more fully with reference to the accompanying drawings. It is to be understood that the present invention may be embodied in different forms and thus should not be construed as being limited to the embodiments set forth herein. It is to be understood that like reference numerals may refer to like elements throughout the specification and drawings, and thus, redundant descriptions may be omitted. As used herein, the term “and/or” includes any and all combinations of one or more of the associated listed items. Expressions such as “at least one of,” when preceding a list of elements, modify the entire list of elements and do not modify the individual elements of the list.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the spirit and scope of the present invention.

It will be understood that singular expressions include plural expressions unless the context clearly indicates otherwise.

It will be understood that when an element or layer is referred to as being “on” another element or layer, the element or layer may be directly on another element or layer or intervening elements or layers.

It will be understood that terms such as connect or combine do not necessarily imply a direct and/or fixed connection or combination between two members, unless the context clearly indicates otherwise, and do not exclude the presence of another member being disposed between the two members that are connected to each other or combined with each other.

In the drawings, various thicknesses, lengths, and angles are shown and while the arrangement shown does indeed represent an embodiment of the present invention, it is to be understood that modifications of the various thicknesses, lengths, and angles may be possible within the spirit and scope of the present invention and the present invention is not necessarily limited to the particular thicknesses, lengths, and angles shown.

“About” or “approximately” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” can mean within one or more standard deviations, or within ±30%, 20%, 10% or 5% of the stated value. Further, it is to be understood that while parameters may be described herein as having “about” a certain value, according to embodiments of the present invention, the parameter may be exactly the certain value or approximately the certain value within a measurement error as would be understood by a person having ordinary skill in the art.

Embodiments of the present invention relate to a display device and a method of manufacturing the same, with a focus on improving flexibility, reducing thickness, and minimizing non-display areas while preventing structural defects like buckling. The display device includes a display panel with distinct regions: a display area, a pad area, and a bending area positioned between them. The display device further includes a protective film with a predetermined thickness and rigidity, attached to a lower surface of the display panel. This protective film may increase structural integrity and may prevent buckling in curved display regions of the display panel, while enabling the display device to remain thin.

According to embodiments of the present invention, the protective film may be excluded from the pad area. This design may allow the pad area to overlap with the display area through the bending of the bending area, without creating excessive thickness. The bending area can achieve a small radius of curvature (e.g., as low as 0.1 mm), thereby reducing the size of the non-display area and expanding the active display region. Additionally, a spacer with a thickness less than that of the protective film can be incorporated in the pad area to further support the structure without compromising the overall thinness of the display device.

Embodiments of the present invention may also include a dummy protective film used during the manufacturing process. The dummy protective film may be temporarily attached to the pad area and may include a photoinitiator in its adhesive layer. When exposed to light (such as UV or metal halide), the photoinitiator reduces the adhesive strength, allowing the dummy protective film to be easily removed after the protective film is properly secured to the display panel. This method ensures a uniform surface during processing, reduces step differences, and simplifies the detachment process without damaging components of the display device.

Furthermore, embodiments of the present invention are versatile in its application, and may be incorporated in a wide range of electronic devices, including, for example, smartphones, tablets, automotive displays (like dashboards and Center Information Displays), and wearable devices. Overall, embodiments of the present invention provide a display device that offers increased durability, reduced thickness, and an expanded display area.

Hereinafter, embodiments of the present invention will be described in detail with reference to the attached drawings.

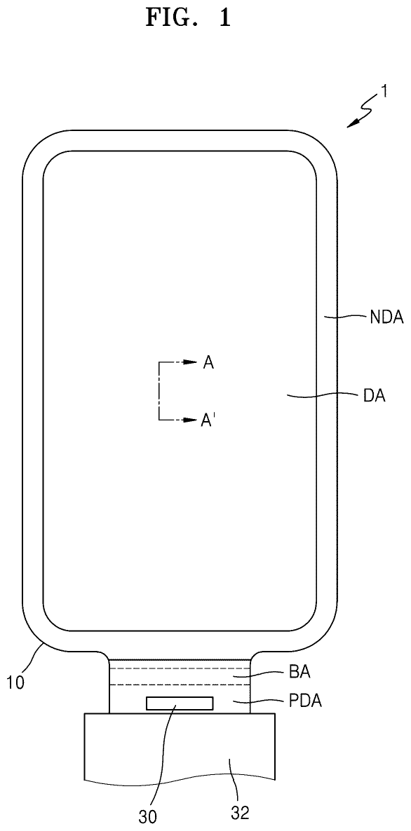

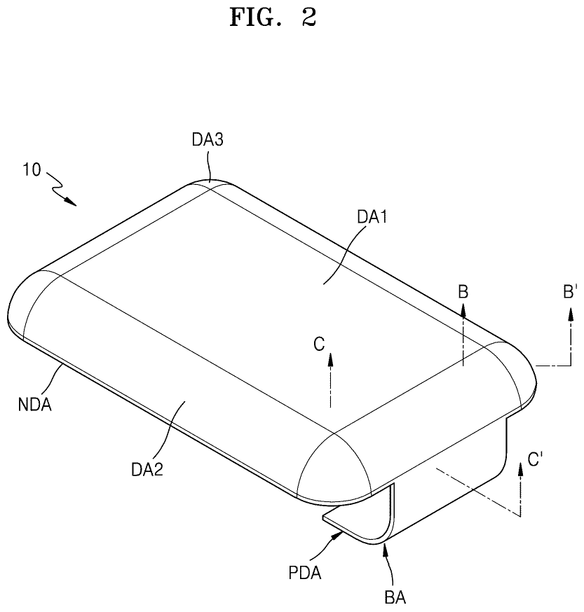

FIG. 1 is a plan view schematically illustrating an example of a display device according to an embodiment of the present invention, and FIG. 2 is a perspective view schematically illustrating an example of a manufacturing process of the display device of FIG. 1.

Referring to FIGS. 1 and 2, a display device 1 is a device that displays a moving image or still image, and it may display a screen on a display panel 10 or perform input and output of data. A display device 1 of this type may be used not only as a display screen of portable electronic devices such as a mobile phone, a smart phone, a tablet personal computer, a mobile communication terminal, an electronic notebook, an electronic book, a portable multimedia player (PMP), a navigation device, an Ultra Mobile PC (UMPC), or the like, but also as a display screen of various electronic devices such as a television, a laptop, a monitor, a billboard, an Internet of Things (IOT) device, or the like. In addition, the display device 1 according to an embodiment of the present invention may be used in electronic devices such as wearable devices such as a smart watch, a watch phone, a glasses-type display, and a head mounted display (HMD). In addition, the display device 1 according to an embodiment of the present invention may be used as a display of various electronic devices, such as a dashboard of an automobile, and a CID (Center Information Display) that is placed on a center fascia or dashboard of an automobile, a room mirror display replacing a side mirror of an automobile, and a display that is placed on the back of a front seat as entertainment for passengers on the rear seats of an automobile.

Referring to FIGS. 1 and 2, a display device 1 according to an embodiment of the present invention includes a display area DA, in which a plurality of pixels are positioned, and a non-display area NDA, which is positioned outside the display area DA. For example, the non-display area NDA may at least partially surround the display area DA. As another example, the non-display area NDA may be located adjacent to one side (e.g., a first side) of the display area DA, and may include a pad area PDA, which is an area where a driving member 30 is located and various electronic components such as integrated circuits or a printed circuit board 32 are electrically attached, and a bending area BA, which is disposed between the display area DA and the pad area PDA. For example, the pad area PDA may be located adjacent to the first side of the display area DA. These display area DA, non-display area NDA, pad area PDA and bending area BA may be defined on a substrate.

In addition, FIG. 1 is a plan view illustrating the shape of a display panel 10 during the manufacturing process of a display device 1, and the display panel 10 may have a shape in which all edges of the display area DA are bent, as illustrated in FIG. 2. Accordingly, the area of the non-display area NDA, as perceived by a user, may be minimized.

For example, the display area DA may include a first display area DA1, second display areas DA2, and third display areas DA3. The second display areas DA2 and the third display areas DA3 may be located at the edges of the first display area DA1.

The first display area DA1 is an area that displays an image on a flat area of the display device 1 and may have an approximately rectangular shape. However, the present invention is not limited thereto. For example, the first display area DA1 may have another polygonal shape, such as a square shape, or a rounded shape, such as a circle or elliptical.

Each of the second display areas DA2 is an area that is bent downward from the sides of the first display area DA1 toward the bottom of the display device 1, and may be an area for displaying an image in a side area of the display device 1. Each of these second display areas DA2 may have a single-curved surface shape that is bent to have a predetermined curvature. For example, the second display areas DA2 may have a single-curved surface shape bent that is with the same or different curvatures.

Each of the third display areas DA3 is an area that displays an image in a corner area of the display device 1, and each of the third display areas DA3 may be located between adjacent second display areas DA2. For example, each of the third display areas DA3 may be adjacent to a corner of the first display area DA1. Each of the third display areas DA3 may have a double-curved surface shape that is bent to have at least two curvatures. For example, the third display areas DA3 may have a double-curved surface shape bent with the same or different curvatures.

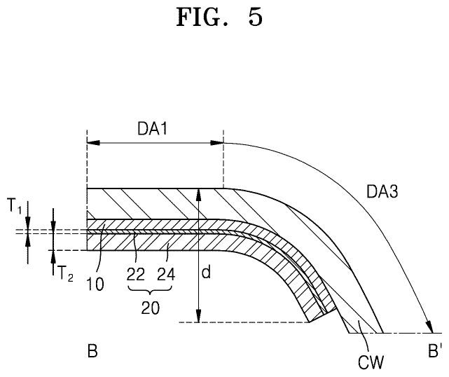

In addition, unlike the tensile stress applied to the display panel 10 when bending the second display area DA2, compressive stress is applied to the display panel 10 when bending the third display area DA3. As a result, buckling defects may occur in the third display area DA3. To prevent such buckling defects, it is desirable to reduce compressive strain that is caused by the compressive stress that occurs when the third display area DA3 is bent. For this purpose, the rigidity of the protective film, which is attached to the lower surface of the display panel 10, may be increased. This will be described later in FIG. 5 and below.

In addition, the pad area PDA may extend from one of the second display areas DA2 and may be positioned below the display area DA due to the bending of the bending area BA. For example, the bending area BA may be positioned between the second display area DA2 and the pad area PDA. Accordingly, the area of the non-display area NDA perceived by a user may be minimized.

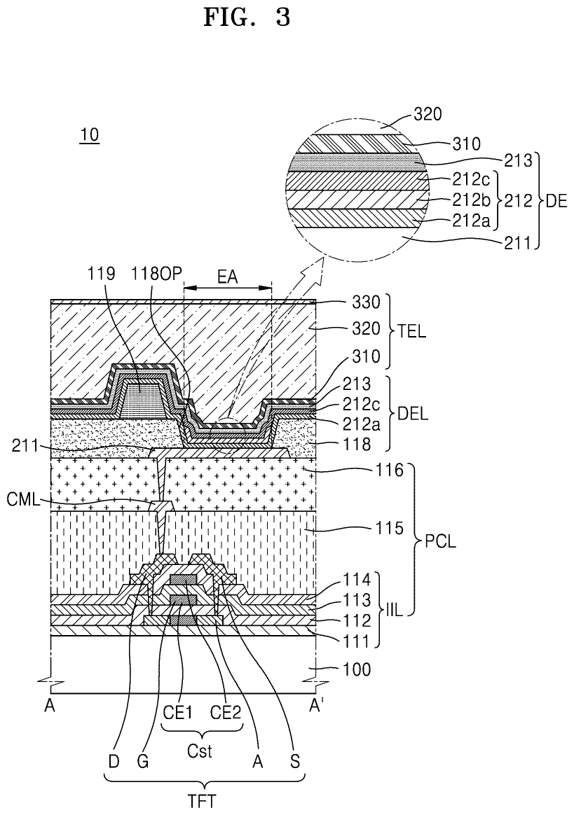

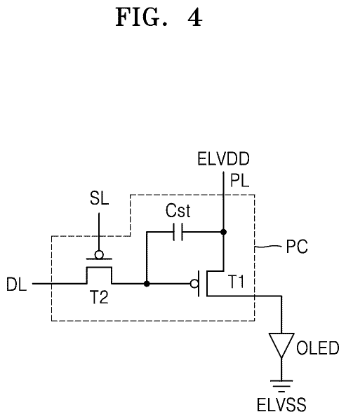

FIG. 3 is a cross-sectional view schematically illustrating an example of the cross-section A-A′ of FIG. 1, and FIG. 4 is a circuit diagram illustrating an example of an equivalent circuit of one (sub)pixel of the display device of FIG. 1.

Referring to FIG. 3, the display device 1 may include a display panel 10. Additionally, the display panel 10 may include a substrate 100, a buffer layer 111, a pixel circuit layer PCL, a display element layer DEL, and a thin film encapsulation layer TFE.

The substrate 100 may be glass or include a polymer resin such as polyethersulfone, polyarylate, polyetherimide, polyethylene naphthalate, polyethylene terephthalate, polyphenylene sulfide, polyimide, polycarbonate, cellulose triacetate, cellulose acetate propionate, or the like. In an embodiment of the present invention, a substrate 100 may have a multilayer structure including a base layer and a barrier layer including the polymer resin. The substrate 100 including a polymer resin may have flexible, rollable, and bendable properties.

A buffer layer 111 may be placed on the substrate 100. The buffer layer 111 may include an inorganic insulator such as silicon nitride, silicon oxynitride, and silicon oxide, and may be a monolayer or a multilayer structure including the inorganic insulator.

A pixel circuit layer PCL may be placed on the buffer layer 111. The pixel circuit layer PCL may include an inorganic insulating layer IIL, a first planarization layer 115, a second planarization layer 116, and a thin film transistor TFT. For example, the first and second planarization layers 115 and 116 may be disposed on the thin film transistor TFT. The inorganic insulating layer IIL may include a first gate insulating layer 112, a second gate insulating layer 113, and an interlayer insulating layer 114.

The thin film transistor TFT may include a semiconductor layer A, and the semiconductor layer A may include polysilicon. In addition, the semiconductor layer A may include, for example, amorphous silicon, an oxide semiconductor, an organic semiconductor, or the like. The semiconductor layer A may include a channel region and a drain region and a source region respectively arranged on sides of the channel region. A gate electrode G may overlap the channel region.

The gate electrode G may include a low resistance metal material. For example, the gate electrode G may include a conductive material including molybdenum (Mo), aluminum (Al), copper (Cu), titanium (Ti), or the like, and may be formed as a multilayer structure or a monolayer including the above materials.

The first gate insulating layer 112, which is disposed between the semiconductor layer A and the gate electrode G, may include an inorganic insulating material such as silicon oxide (SiO2), silicon nitride (SiNX), silicon oxynitride (SiON), aluminum oxide (Al2O3), titanium oxide (TiO2), tantalum oxide (Ta2O5), hafnium oxide (HfO2), zinc oxide (ZnOX), or the like. Zinc oxide (ZnOX) may be zinc oxide (ZnO) and/or zinc peroxide (ZnO2).

The second gate insulating layer 113 may cover the gate electrode G. The second gate insulating layer 113 may, similarly to the first gate insulating layer 112, include an inorganic insulating material such as silicon oxide (SiO2), silicon nitride (SiNX), silicon oxynitride (SiON), aluminum oxide (Al2O3), titanium oxide (TiO2), tantalum oxide (Ta2O5), hafnium oxide (HfO2), zinc oxide (ZnOx), or the like. Zinc oxide (ZnOX) may be zinc oxide (ZnO) and/or zinc peroxide (ZnO2).

An upper electrode CE2 of a storage capacitor Cst may be placed on the second gate insulating layer 113. The upper electrode CE2 may overlap the gate electrode G that is below it. In this configuration, the gate electrode G and the upper electrode CE2, with the second gate insulating layer 113 positioned between them, may form a storage capacitor Cst of the pixel circuit. For example, the gate electrode G may function as a lower electrode CE1 of the storage capacitor Cst. In this manner, a storage capacitor Cst and a thin film transistor TFT may be formed in an overlapping structure. In embodiments of the present inventive concept, the storage capacitor Cst may be formed so as not to overlap the thin film transistor TFT.

The upper electrode CE2 may include, for example, aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a monolayer or a multiplayer structure of the materials.

The interlayer insulating layer 114 may cover the upper electrode CE2. The interlayer insulating layer 114 may include, for example, silicon oxide (SiO2), silicon nitride (SiNX), silicon oxynitride (SiON), aluminum oxide (Al2O3), titanium oxide (TiO2), tantalum oxide (Ta2O5), hafnium oxide (HfO2), zinc oxide (ZnOx), or the like. Zinc oxide (ZnOX) may be zinc oxide (ZnO) and/or zinc peroxide (ZnO2). The interlayer insulating layer 114 may be a monolayer or a multilayer structure including the inorganic insulating materials.

A drain electrode D and a source electrode S may each be positioned on the interlayer insulating layer 114. The drain electrode D and the source electrode S may penetrate the first gate insulating layer 112, the second gate insulating layer 113, and the interlayer insulating layer 114 and may be respectively connected to the drain region and the source region of the semiconductor layer A. The drain electrode D and the source electrode S may include a material having good conductivity. The drain electrode D and the source electrode S may include a conductive material including, for example, molybdenum (Mo), aluminum (Al), copper (Cu), titanium (Ti), or the like, and may be formed as a multilayer structure or a monolayer including the materials. In an embodiment of the present invention, the drain electrode D and the source electrode S may have a multilayer structure of Ti/Al/Ti.

A first planarization layer 115 may be arranged to cover the drain electrode D and the source electrode S. The first planarization layer 115 may include an organic insulating layer. The first planarization layer 115 may include an organic insulator such as a general-purpose polymer such as polymethylmethacrylate (PMMA) or polystyrene (PS), a polymer derivative having a phenolic group, an acrylic polymer, an imide polymer, an aryl ether polymer, an amide polymer, a fluorinate polymer, a p-xylene polymer, a vinyl alcohol polymer, and a blend thereof.

The connection electrode CML can be placed on the first planarization layer 115. The connection electrode CML may be connected to the drain electrode D or the source electrode S through a contact hole of the first planarization layer 115. The connection electrode CML may include a material with good conductivity. The connection electrode CML may include a conductive material including, for example, molybdenum (Mo), aluminum (Al), copper (Cu), titanium (Ti), or the like, and may be formed as a multilayer structure or a monolayer including the materials. In an embodiment of the present invention, a connection electrode CML may have a multilayer structure of Ti/Al/Ti.

A second planarization layer 116 may be arranged to cover the connection electrode CML. The second planarization layer 116 may include an organic insulating layer. The second planarization layer 116 may include an organic insulator such as a general-purpose polymer such as polymethylmethacrylate (PMMA) or polystyrene (PS), a polymer derivative having a phenolic group, an acrylic polymer, an imide polymer, an aryl ether polymer, an amide polymer, a fluorinate polymer, a p-xylene polymer, a vinyl alcohol polymer, and a blend thereof.

A display element layer DEL may be placed on a pixel circuit layer PCL. The display element layer DEL may include a display element DE. The display elements DE may be organic light-emitting diode OLED. A pixel electrode 211 of the display element DE may be electrically connected to the connection electrode CML through a contact hole of the second planarization layer 116.

The pixel electrode 211 may include a conductive oxide such as indium tin oxide (ITO), indium zinc oxide (IZO), zinc oxide (ZnO), indium oxide (In2O3), indium gallium oxide (IGO), or aluminum zinc oxide (AZO). In an embodiment of the present invention, the pixel electrode 211 may include a reflective film including silver (Ag), magnesium (Mg), aluminum (Al), platinum (Pt), palladium (Pd), gold (Au), nickel (Ni), neodymium (Nd), iridium (Ir), chromium (Cr), or compounds thereof. In an embodiment of the present invention, the pixel electrode 211 may further include a film formed of ITO, IZO, ZnO or In2O3 above/below the reflective film.

A pixel definition film 118 having an opening 118OP exposing the central portion of the pixel electrode 211 may be placed on the pixel electrode 211. The pixel definition film 118 may include an organic insulator and/or an inorganic insulator. The opening 118OP may define an emission area EA of light emitted from the display element DE (hereinafter referred to as emission area). For example, the width of the opening 118OP may correspond to the width of the emission area EA of the display element DE.

In an embodiment of the present invention, the pixel definition film 118 includes a light-blocking material and may be black in color. The light-blocking material may include, for example, a resin or paste including carbon black, carbon nanotubes, black dye, metal particles such as nickel, aluminum, molybdenum and an alloy thereof, metal oxide particles (e.g. chromium oxide), metal nitride particles (e.g. chromium nitride), or the like. When the pixel definition film 118 includes a light-blocking material, reflection of external light by metal structures arranged below the pixel definition film 118 may be reduced.

A spacer 119 may be placed on the pixel definition film 118. The spacer 119 may be used to prevent damage to the substrate 100 in a manufacturing process of a display device. When manufacturing a display panel 10, a mask sheet may be used. At this time, when the mask sheet enters the opening 118OP of the pixel definition film 118 or is in close contact with the pixel definition film 118 to deposit a deposition material on the substrate 100, a defect in which a part of the substrate 100 is damaged or broken by the mask sheet may be prevented.

The spacer 119 may include an organic insulator such as polyimide. In addition, the spacer 119 may include an inorganic insulator such as silicon nitride or silicon oxide or may include an organic insulator and an inorganic insulator.

In an embodiment of the present invention, the spacer 119 may include a material that is different from that of the pixel definition film 118. In addition, in an embodiment of the present invention, the spacer 119 may include the same material as the pixel definition film 118, in which case the pixel definition film 118 and the spacer 119 may be formed together in a mask process using a halftone mask or the like.

An intermediate layer 212 may be arranged on the pixel definition film 118. The intermediate layer 212 may include a light-emitting layer 212b arranged in the opening 118OP of the pixel definition film 118. The light-emitting layer 212b may include a polymer or low molecular organic material that emits light of a predetermined color.

A first functional layer 212a and a second functional layer 212c may be arranged below and above the light-emitting layer 212b, respectively. The first functional layer 212a may include, for example, a hole transport layer (HTL) or a hole transport layer and a hole injection layer (HIL). The second functional layer 212c is a component positioned on the light-emitting layer 212b and may be optional. The second functional layer 212c may include an electron transport layer (ETL) and/or an electron injection layer (EIL). The first functional layer 212a and/or the second functional layer 212c may be a common layer formed to cover the substrate 100, similar to a counter electrode 213 described later. For example, the first functional layer 212a and/or the second functional layer 212c may be a common layer formed to cover the entire substrate 100.

The counter electrode 213 may be made of a conductive material having a low work function. For example, the counter electrode 213 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. In addition, the counter electrode 213 may further include a layer such as ITO, IZO, ZnO or In2O3 on the (semi)transparent layer including the material described above.

In embodiments of the present inventive concept, a capping layer may be further disposed on the counter electrode 213. The capping layer may include LiF, an inorganic material, and/or an organic material.

An encapsulation layer TFE may be placed on the counter electrode 213. In an embodiment of the present invention, the encapsulation layer TFE includes at least one inorganic encapsulation layer and at least one organic encapsulation layer, and FIG. 3 illustrates that the encapsulation layer TFE includes a first inorganic encapsulation layer 310, an organic encapsulation layer 320, and a second inorganic encapsulation layer 330 that are sequentially laminated on the display element layer DEL.

For example, the first inorganic encapsulation layer 310 and the second inorganic encapsulation layer 330 may include one or more inorganic materials of aluminum oxide, titanium oxide, tantalum oxide, hafnium oxide, zinc oxide, silicon oxide, silicon nitride, and/or silicon oxynitride. The organic encapsulation layer 320 may include a polymer-based material. Polymer-based materials may include acrylic resins, epoxy resins, polyimides, and polyethylene. In an embodiment of the present invention, the organic encapsulation layer 320 may include acrylate.

FIG. 4 is an equivalent circuit diagram schematically showing a pixel circuit PC that may be applied to a display panel 10.

Referring to FIG. 4, a pixel circuit PC may be connected to a display element, for example, an organic light-emitting diode OLED. The pixel circuit PC may include a driving thin film transistor T1, a switching thin film transistor T2, and a storage capacitor Cst. Additionally, the organic light-emitting diodes OLED may emit red, green, or blue light, or may emit red, green, blue, or white light.

The switching thin film transistor T2 is connected to a scan line SL and a data line DL and may transmit a data signal or data voltage, which is input from the data line DL, to the driving thin film transistor T1 based on a scan signal or switching voltage input from the scan line SL. The storage capacitor Cst is connected to the switching thin film transistor T2 and a driving voltage line PL and may store a voltage corresponding to the difference between the voltage that is received from the switching thin film transistor T2 and a first power supply voltage ELVDD that is supplied to the driving voltage line PL.

The driving thin film transistor T1 is connected to the driving voltage line PL and the storage capacitor Cst and may control a driving current flowing through the organic light-emitting diode OLED from the driving voltage line PL in response to the voltage value stored in the storage capacitor Cst. The organic light-emitting diode OLED may emit light with a certain brightness depending on the driving current. The counter electrode of the organic light-emitting diode OLED may be supplied with a second power supply voltage ELVSS.

Although FIG. 4 illustrates that the pixel circuit PC includes two thin film transistors and one storage capacitor, the pixel circuit PC may include three, four, five or more thin film transistors.

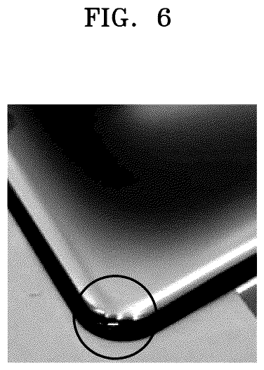

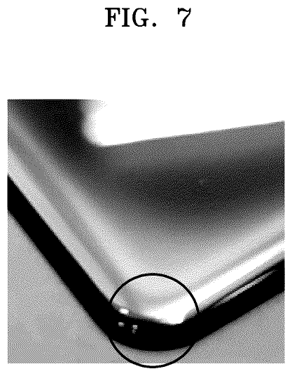

FIG. 5 is a cross-sectional view schematically illustrating an example of the cross-section B-B′ of FIG. 2, and FIGS. 6 and 7 are drawings illustrating the corner display areas of FIG. 2, respectively.

Referring to FIG. 5, a cover window CW may be attached to the display panel 10. The cover window CW may be attached to the display panel 10 by an adhesive layer. For example, the adhesive layer may include an adhesive material such as an optical clear adhesive (OCA) or a pressure sensitive adhesive (PSA).

The cover window CW may comprise glass or plastic. For example, the cover window CW may be made of ultra-thin glass (UTG) whose strength is strengthened through chemical strengthening or thermal strengthening.

A protective film 20 may be attached to the lower portion of the display panel 10. For example, the protective film 20 may be attached to a lower surface of the display panel. The protective film 20 may be positioned to overlap with at least one of the first display area DA1 of FIG. 1, the second display area DA2 of FIG. 1, or the third display area DA3 of FIG. 1. For example, the protective film 20 may be positioned below at least one of the first display area DA1 of FIG. 1, the second display area DA2 of FIG. 1, or the third display area DA3 of FIG. 1. The protective film 20 may be attached to the lower surface of the display panel 10 except for a bending area BA and a pad area PDA. For example, the protective film 20 may be attached to the entire lower surface of the display panel 10 except for a bending area BA and a pad area PDA.

The protective film 20 may include a protective film base 24 and an adhesive layer 22 (e.g., a first adhesive layer). The protective film base 24 may include, for example, polyethylene terephthalate (PET) or polyimide (PI). For example, the protective film base 24 may include polyethylene terephthalate (PET) to ensure sufficient rigidity. Additionally, the adhesive layer 22 may include various adhesive materials.

The protective film 20 may protect the lower surface of the substrate 100 and includes an inherent rigidity, which may vary depending on the thickness of the protective film 20.

In addition, as explained above, although compressive stress is applied to the third display area DA3, the sufficient thickness of the protective film 20 may help maintain its rigidity, thereby reducing strain caused by the compressive stress. This reduction in strain may effectively prevent the occurrence of a buckling phenomenon in the third display area DA3.

For this purpose, the protective film 20 may have a thickness of about 100 μm to about 130 μm. In addition, since the rigidity of the protective film 20 is mainly determined by the protective film base 24, a thickness T1 of the adhesive layer 22 may be about 10% to about 20% of a thickness T2 of the protective film base 24. For example, when the thickness T2 of the protective film base 24 is about 100 μm, the thickness T1 of the adhesive layer 22 may be about 10 μm to about 20 μm. When the thickness T1 of the adhesive layer 22 is less than 10% of the thickness T2 of the protective film base 24, peeling may occur between the protective film 20 and the display panel 10, and when the thickness T1 of the adhesive layer 22 is greater than 20% of the thickness T2 of the protective film base 24, it may be difficult to sufficiently secure the rigidity of the protective film 20, so a buckling phenomenon may occur in the third display area DA3.

For example, when the protective film 20 has a thickness of about 100 μm to about 130 μm, with the protective film base 24 having a predetermined thickness (e.g., T2) and the adhesive layer 22 having a thickness (e.g., T1) that is about 10% to about 20% of the thickness of the protective film base 24, the buckling phenomenon in the third display area DA3 may be prevented while preventing peeling between the protective film 20 and the display panel 10.

FIGS. 6 and 7 are drawings each illustrating a corner display area of FIG. 2, and both FIGS. 6 and 7 illustrate the results of a stability test (uHAST) conducted for 240 hours at about 85% humidity and about 85° C. on a display device formed with a p-depth d of about 553 μm. Here, FIG. 6 shows a case where the protective film 20 has a thickness of about 88 μm, and FIG. 7 shows a case where the protective film 20 has a thickness of about 113 μm.

As may be seen in FIGS. 6 and 7, in the case of FIG. 6, a buckling phenomenon occurred in the third display area DA3, but in the case of FIG. 7, a buckling phenomenon did not occur in the third display area DA3. This is because the resistance to compressive stress increases as the thickness of the protective film 20 increases, thereby reducing compressive strain.

In addition, as the thickness of the protective film 20 increases, the rigidity of the protective film 20 increases. However, when the protective film 20 becomes too thick, the thickness of the display panel 10 increases, and it becomes difficult to bend the third display area DA3. Therefore, the protective film 20 may have a thickness of about 130 μm or less.

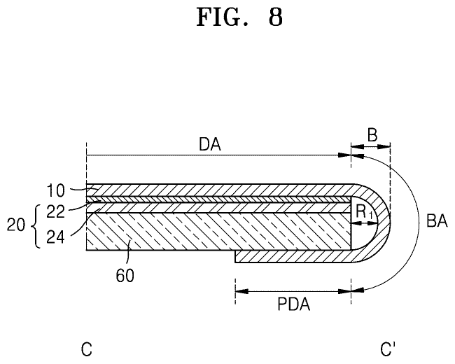

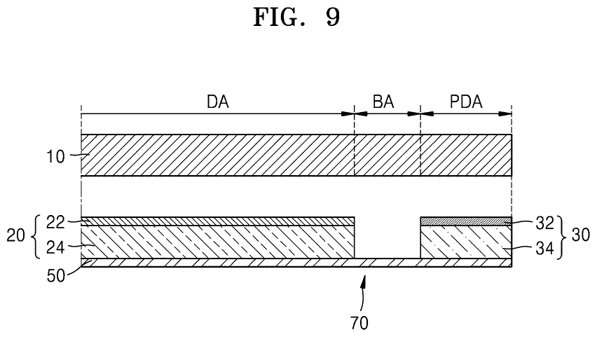

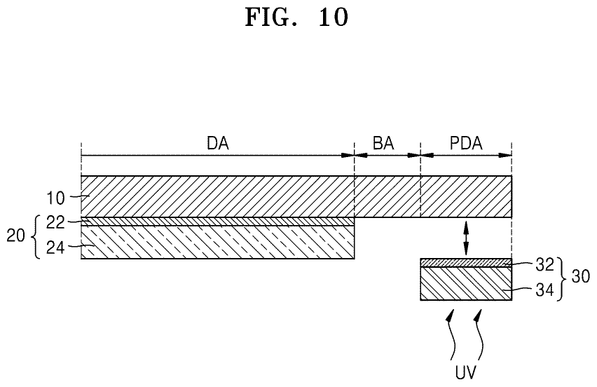

FIG. 8 is a cross-sectional view schematically illustrating an example of the cross-section C-C′ of FIG. 2, and FIGS. 9 and 10 are cross-sectional views schematically illustrating a manufacturing process of a display device according to FIG. 8.

First, referring to FIG. 8, the pad area PDA may be positioned to overlap the display area DA due to the bending of the bending area BA. A protective film 20 may be positioned on the bottom surface of the display panel 10 corresponding to the display area DA, and a cover layer 60 may be positioned at the lower surface of the protective film 20. The pad area PDA may be positioned on the cover layer 60 in an overlapping arraignment with the display area DA due to the bending of the bending area BA.

The protective film 20 may include a protective film base 24 and an adhesive layer 22. The protective film base 24 may include, for example, polyethylene terephthalate (PET) or polyimide (PI). For example, the protective film base 24 may include polyethylene terephthalate (PET) to ensure sufficient rigidity. Additionally, the adhesive layer 22 may include various adhesive materials.

In addition, to prevent peeling between the protective film 20 and the display panel 10 while preventing a buckling phenomenon in the third display area DA3 of FIG. 2, the protective film 20 may have a thickness of about 100 μm to about 130 μm, and the thickness T1 of the adhesive layer 22 may be about 10% to about 20% of the thickness T2 of the protective film base 24.

A protective film 20 like this is not located in the bending area BA and the pad area PDA. Since the protective film 20 is not located in the bending area BA, peeling between the protective film base 24, which has rigidity, and the display panel 10 may be prevented when the bending area BA is bent.

In addition, in comparative examples, a protective film 20 was also positioned on the pad area PDA, and when the pad area PDA was bent, the protective film 20 overlapped with itself. However, according to embodiments of the present invention, by not positioning the protective film 20 in the pad area PDA, the thickness of the protective film 20 can be increased to increase rigidity without increasing the overall thickness of the display device. Instead, this approach may contribute to reducing the thickness of the display device.

In addition, since the protective film 20 is not positioned on the pad area PDA, the display panel 10 may be bent with a small radius of curvature R1, thereby reducing the area occupied by the bending area BA. For example, the radius of curvature R1 in the bending area BA may be about 0.1 mm to about 0.4 mm. For example, the bottom border width B of the display device may be reduced, so that the non-display area may be reduced and the display area DA may relatively expanded.

A cover layer 60 may include at least one of a cushion layer, which absorbs external impact and may prevent the display panel 10 from being damaged, or a metal plate that supports the display panel 10.

For example, the cushion layer may include a polymer resin such as polyurethane, polycarbonate, polypropylene, or polyethylene, or an elastic material such as a sponge foamed with rubber, a urethane-based material, or an acrylic material.

The metal plate may include a material having an elastic modulus of 60 GPa or greater at room temperature (e.g., about 68° F. to about 77° F.). The metal plate may include a single metal material or an alloy of multiple metal materials to increase the heat dissipation performance of the display device. For example, the metal plate may be SUS304, but the present invention is not limited thereto and the metal plate may include various metal materials.

A method of manufacturing such a display device is described with reference to FIGS. 9 and 10.

First, referring to FIG. 9, a display panel 10 including a display area DA, a pad area PDA, and a bending area BA that is disposed between the display area DA and the pad area PDA is prepared, and a protective film member 70, in which a protective film 20 is formed on a carrier film 50, is prepared.

The protective film member 70 may include a dummy protective film 30 in addition to the protective film 20. The protective film member 70 may have the same shape as the display panel 10, and the dummy protective film 30 may be at a position corresponding to the pad area PDA of the display panel 10.

In addition, a portion of the dummy protective film 30 may be removed from the carrier film 50 at a position corresponding to the bending area BA of the display panel 10. The carrier film 50 may have the same shape as the display panel 10.

The protective film 20 may be formed by sequentially laminating a protective film base 24 and an adhesive layer 22 on the carrier film 50. The dummy protective film 30 may be formed by sequentially laminating a dummy protective film base 34 and a dummy adhesive layer 32 on the carrier film 50.

To prevent defects due to step differences during the manufacturing process of the display device, the protective film 20 and the dummy protective film 30 may have the same thickness as each other. Additionally, the protective film base 24 and the dummy protective film base 34 may include the same material as each other.

In addition, the dummy adhesive layer 32 may further include a photoinitiator, unlike the adhesive layer 22. When the dummy adhesive layer 32 is exposed to light, such as ultraviolet rays or metal hydride, the photoinitiator increases the crosslinking density, thereby reducing an adhesive strength.

The dummy adhesive layer 32 may include a photoinitiator in an amount of at least 0.1 wt % and not more than 5 wt %. If the content of the photoinitiator is less than 0.1 wt %, the reduction in adhesive strength of the dummy adhesive layer 32 upon exposure to ultraviolet light, or the like may be minimal. If the content of the photoinitiator is more than 5 wt %, the reduced applicability of the dummy adhesive layer 32 may make it difficult to maintain uniform thickness between the protective film 20 and the dummy protective film 30. In addition, this may hinder an attachment of the dummy protective film 30 to the display panel 10 during the manufacturing process of the display device.

Next, as shown in FIG. 10, the protective film 20 and the dummy protective film 30 of the protective film member 70 are attached to the display panel 10. Then, the carrier film 50 is removed from the protective film member 70, and then the dummy protective film 30 is irradiated with light such as ultraviolet rays or metal halide to reduce the adhesive strength of the dummy adhesive layer 32, thereby detaching the dummy protective film 30 from the display panel 10.

For example, the dummy adhesive layer 32 is attached to the display panel 10 with an adhesive strength of about 1 kgf/cm² to about 2 kgf/cm², but after exposure to light, such as ultraviolet rays or metal halide, the adhesive strength decreases to less than about 50 gf/cm², allowing the dummy protective film 30 to be easily removed from the display panel 10.

In this way, after the dummy protective film 30 is removed from the display panel 10, the bending area BA is bent so that the pad area PDA is positioned below the display area DA. Even if the thickness of the protective film 20 is increased to prevent a buckling phenomenon in the corner display area DA3 of FIG. 2, the overall thickness of the display device is reduced and a lower border area of the display device are reduced, thereby reducing a non-display area.

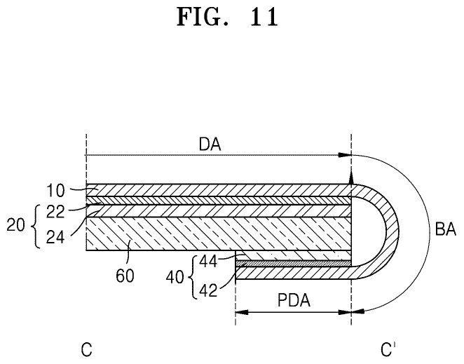

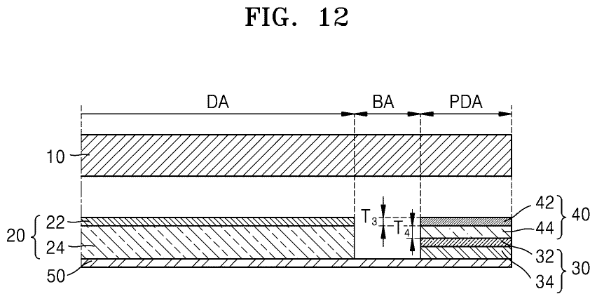

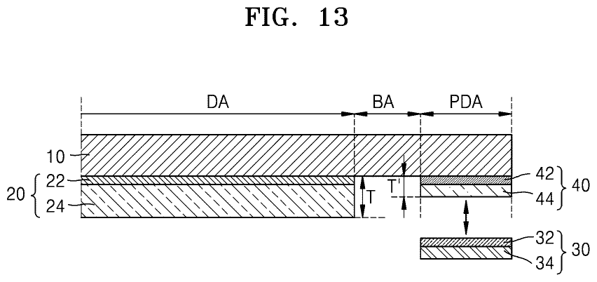

FIG. 11 is a cross-sectional view schematically illustrating an example of the cross-section C-C′ of FIG. 2, and FIGS. 12 and 13 are cross-sectional views schematically illustrating a manufacturing process of a display device according to FIG. 11.

First, referring to FIG. 11, a pad area PDA may be positioned to overlap a display area DA due to the bending of the bending area BA. A protective film 20 may be positioned on the bottom surface of a display panel 10, and a cover layer 60 may be positioned below the protective film 20. The pad area PDA is positioned on the cover layer 60, and a spacer 40 may be placed between the pad area PDA of the display panel 10 and the cover layer 60.

The protective film 20 may include a protective film base 24 and an adhesive layer 22. The protective film base 24 may include, for example, polyethylene terephthalate (PET) or polyimide (PI). For example, the protective film base 24 may include polyethylene terephthalate (PET) to ensure sufficient rigidity. Additionally, the adhesive layer 22 may include various adhesive materials.

In addition, to prevent peeling between the protective film 20 and the display panel 10 while preventing a buckling phenomenon in the third display area DA3 of FIG. 2, the protective film 20 may have a thickness of about 100 μm to about 130 μm, and the thickness T1 of the adhesive layer 22 may be about 10% to about 20% of the thickness T2 of the protective film base 24.

A protective film 20 like this is not located in the bending area BA. Since the protective film 20 is not located in the bending area BA, peeling between the protective film base 24, which has rigidity, and the display panel 10 may be prevented when the bending area BA is bent.

A spacer 40 may be placed between the pad area PDA of the display panel 10 and the cover layer 60. The spacer 40 may include a second adhesive layer 42 and a spacer base 44.

The second adhesive layer 42 may include the same material as the adhesive layer 22, and the spacer base 44 may include the same material as the protective film base 24. However, the spacer base 44 may be thinner than the protective film base 24. Accordingly, even if the thickness of the protective film 20 is increased to increase the rigidity of the protective film 20, the overall thickness of the display device may be prevented from increasing or may be reduced.

In addition, because the spacer base 44 has a thickness that is smaller than that of the protective film 20 and is positioned in the pad area PDA, the display panel 10 may be bent with a small radius of curvature, thereby reducing the area occupied by the non-display area of the display device and expanding the display area DA.

The cover layer 60 may include a cushion layer, a metal plate, or the like. The cushion layer may absorb an external impact to prevent the display panel 10 from being damaged, and the metal plate may support the display panel 10.

A method of manufacturing such a display device is described with reference to FIGS. 12 and 13.

Referring to FIGS. 12 and 13, first, a display panel 10 is prepared, and a protective film member 70, in which a protective film 20 is formed on a carrier film 50, is prepared.

The protective film member 70 may have the same shape as the display panel 10. The protective film member 70 may include, in addition to the protective film 20, a dummy protective film 30 and a spacer 40 sequentially laminated at a position corresponding to the pad area PDA.

The protective film 20 is removed from the carrier film 50 at a position corresponding to the bending area BA of the display panel 10, thereby preventing peeling between the protective film 20 and the display panel 10 when the display panel 10 is bent in the bending area BA.

In addition, the overall thickness of the protective film 20 may be equal to the sum of the thicknesses of the dummy protective film 30 and the spacer 40. Therefore, the thickness T′ of the spacer 40 may be smaller than the thickness T of the protective film 20. For example, the thickness T3 of a second adhesive layer 42 may be smaller than the thickness of an adhesive layer 22 of the protective film 20, and the thickness T4 of a spacer base 44 may be smaller than the thickness of a protective film base 24. For example, the thickness T4 of the spacer base 44 may be about 60% or less of the thickness of the protective film base 24.

The protective film base 24, the dummy protective film base 34, and the spacer base 44 may include the same material as each other, and the adhesive layer 22 and the second adhesive layer 42 may include the same material as each other. However, a dummy adhesive layer 32 may further include a photoinitiator, unlike the adhesive layer 22 and the second adhesive layer 42. When the dummy adhesive layer 32 is irradiated with light, such as ultraviolet rays or metal hydride, the photoinitiator increases the crosslinking density, thereby reducing an adhesive strength.

The dummy adhesive layer 32 may include a photoinitiator in an amount of at least 0.1 wt % and not more than 5 wt %. If the content of the photoinitiator is less than 0.1 wt %, the reduction in adhesive strength of the dummy adhesive layer 32 by irradiation with ultraviolet light, or the like may be minimal. If the content of the photoinitiator is more than 5 wt %, the reduced applicability of the dummy adhesive layer 32 may make it difficult to maintain uniform thickness between the protective film 20 and the dummy protective film 30. In addition, this may hinder an attachment of the dummy protective film 30 to the display panel 10 during the manufacturing process of the display device.

Next, as shown in FIG. 13, the protective film member 70 and the display panel 10 are attached, and then the dummy protective film 30 is irradiated with light such as ultraviolet rays or metal halide to reduce the adhesive strength of the dummy adhesive layer 32, thereby separating the dummy protective film 30 from the spacer 40.

For example, the dummy adhesive layer 32 is attached to the spacer 40 with an adhesive strength of about 1 kgf/cm² to about 2 kgf/cm², but after irradiating with light such as ultraviolet rays or metal halides, the adhesive strength decreases to less than about 50 gf/cm², allowing the dummy protective film 30 to be easily removed from the spacer 40.

In this way, after removing the dummy protective film 30, the bending area BA is bent so that the pad area PDA, to which the spacer 40 is attached, is positioned below the display area DA. Even if the thickness of the protective film 20 is increased to prevent a buckling phenomenon in the corner display area DA3 of FIG. 2, the overall thickness of the display device is reduced and the lower border area of the display device is reduced, thereby reducing the non-display area.

According to the present invention, the buckling phenomenon is prevented in the corner display area of the display device, and the thickness and non-display area of the display device are reduced, so that the display area may be relatively expanded.

The display device 1 according to an embodiment of the present invention may be applied to various electronic devices. An electronic device according to an embodiment of the present invention may include the display device 1 described above, and may further include a module or device having additional functions, in addition to the display device 1.

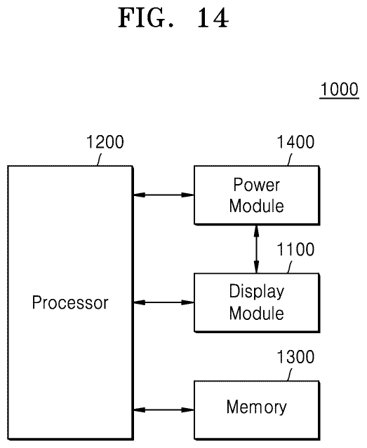

FIG. 14 is a block diagram of an electronic device according to an embodiment of the present invention. Referring to FIG. 14, an electronic device 1000 according to an embodiment of the present invention may include a display module 1100, a processor 1200, a memory 1300, and a power module 1400.

The processor 1200 may include at least one of a central processing unit (CPU), an application processor (AP), a graphics processing unit (GPU), a communication processor (CP), an image signal processor (ISP), or a controller.

The memory 1300 may store data information for operation of the processor 1200 or the display module 1100. An image data signal and/or an input control signal may be transmitted to the display module 1100 in a case where the processor 1200 executes an application that is stored in the memory 1300, and the display module 1100 may output image information through a display screen by processing the received signal.

The power module 1400 may include a power supply module, such as a power adapter or a battery device, and a power conversion module which converts power supplied by the power supply module to generate power for the operation of the electronic device 1000.

At least one of respective components of the electronic device 1000 may be included in the display device according to embodiments of the present invention described above. In embodiments of the present invention, some of the individual modules functionally included in a module may be included in a display device, while others may be provided separately from the display device. For example, the display device may include the display module 1100, and the processor 1200, the memory 1300, and the power module 1400 may be provided in the form of other apparatuses in the electronic device 1000 other than the display device.

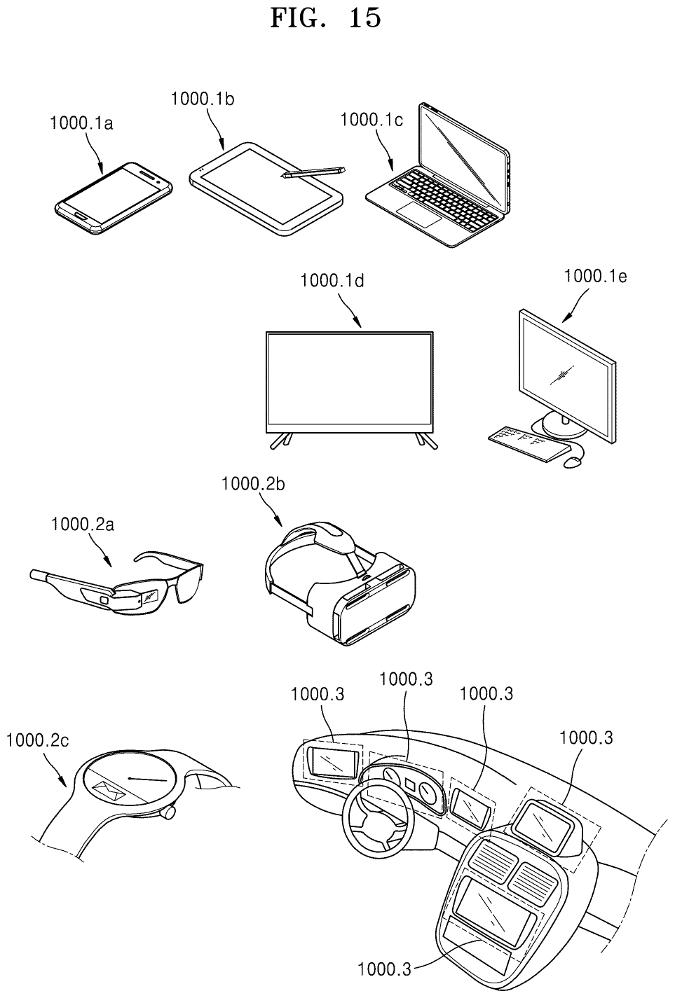

FIG. 15 illustrates schematic views of individual electronic devices according to various embodiments of the present invention.

Referring to FIG. 15, various electronic devices according to embodiments of the present invention, to which the display device is applied, may include: an electronic device for displaying an image, such as a smart phone 1000.1a, a tablet PC 1000.1b, a laptop computer 1000.1c, a TV set 1000.1d, a desk monitor 1000.1e, and the like; a wearable electronic device including a display module, such as smart glasses 1000.2a, a head mounted display 1000.2b, a smart watch 1000.2c, and the like; and an electronic device 1000.3 for vehicles including a display module, such as a center information display (CID) arranged on an instrument panel, center fascia, or dashboard of a vehicle, a room mirror display, and the like.

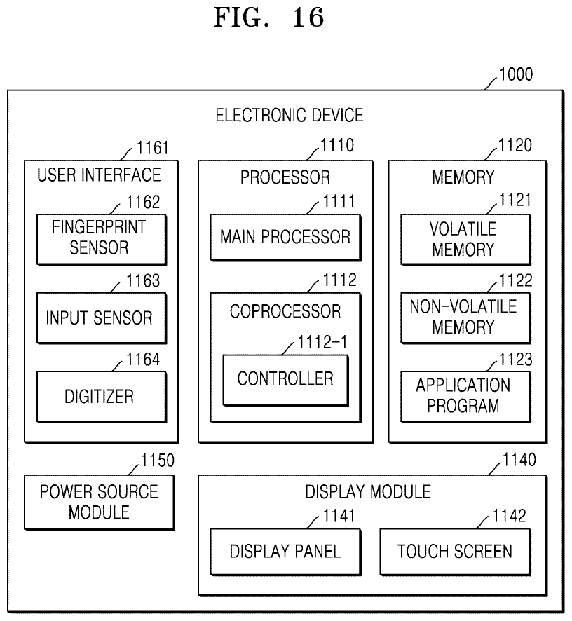

FIG. 16 is a diagram illustrating an electronic device according to an embodiment of the present invention. Referring to FIG. 16, the electronic device 1000 according to an embodiment of the present invention may output various information (e.g., images, text, music, etc.) through a display module 1140, which, for example, may correspond to the display device 1 shown in FIG. 1. When a processor 1110 executes an application stored in a memory 1120, the display module 1140 may provide application information to a user through a display panel 1141.

In some embodiments of the present invention, the electronic device 1000 may be configured as a smartphone, camera, smart TV, monitor, smartwatch, tablet, automotive display, or AR/VR headset. For example, the electronic device 1000 may be a smartphone including a touch-sensitive display area (e.g., the display area DA) for interaction and a non-display area (e.g., non-display area NDA) including sensors and circuits for enhanced functionality. For example, the electronic device 1000 may be a television or monitor including a large display area DA for high-resolution video playback and a non-display area incorporating driving circuits or connectivity modules for external inputs. For example, the electronic device 1000 may be a smartwatch including a display area DA optimized for compact and high-clarity visuals and a non-display area integrating biometric sensors for health monitoring. In some cases, the electronic device 1000 be an AR/VR headset.

In some embodiments of the present invention, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device 1 shown in FIG. 1.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display unit shown in FIG. 1.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

For example, the disclosure about the electronic device 1000 of FIG. 16 may be combinable with the disclosure about the electronic device 1000 of FIG. 16 and the electronic devices of FIG. 15.

While the present invention has been described with reference to embodiments thereof, it will be understood by those of ordinary skill in the art that various changes in form and details may be made thereto without departing from the spirit and scope of the present invention.

What is claimed is:

1. A display device comprising;
a display panel including a display area, a pad area and a bending area, wherein the pad area is located adjacent to a first side of the display area, and the bending area is disposed between the display area and the pad area;
a protective film attached to a lower surface of the display panel and including a protective film base and a first adhesive layer; and
a cover layer located below the protective film,
wherein the pad area is positioned on the cover layer in an overlapping arrangement with the display area due to bending of the bending area, and
the protective film has a thickness of about 100 μm to about 130 μm, and a thickness of the first adhesive layer is about 10% to about 20% of a thickness of the protective film base.

2. The display device of claim 1, wherein
the display area includes a first display area, second display areas, and third display areas, wherein the first display area is a flat area, wherein the second display areas are located at edges of the first display area, and the third display areas are located between the second display areas, and
the second display areas each have a single-curved surface shape, and the third display areas each have a double-curved surface shape.

3. The display device of claim 2, wherein
the protective film overlaps with at least one of the first display area, the second display areas, or the third display areas.

4. The display device of claim 1, wherein
the pad area is positioned directly on the cover layer.

5. The display device of claim 4, wherein
the bending area has a radius of curvature between 0.1 mm to 0.4 mm.

6. The display device of claim 1, further comprising:
a spacer disposed between the pad area of the display panel and the cover layer,
wherein a thickness of the spacer is smaller than the thickness of the protective film.

7. The display device of claim 6, wherein
the spacer comprises a second adhesive layer and a spacer base, and
a thickness of the spacer base is about 60% or less of the thickness of the protective film base.

8. The display device of claim 1, wherein
the cover layer includes at least one of a cushion layer or a metal plate.

9. The display device of claim 8, wherein
the metal plate includes a material having an elastic modulus of 60 GPa or more at a temperature of about 68° F. to about 77° F.

10. The display device of claim 1, wherein
the display panel includes an organic light-emitting diode.

11. A method of manufacturing a display device, the method comprising:
preparing a display panel including a display area, a pad area, and a bending area that is disposed between the display area and the pad area;
preparing a protective film member, in which a protective film and a dummy protective film are formed on a carrier film having a same shape as the display panel;
attaching the protective film and the dummy protective film to the display panel;
removing the carrier film from the protective film member;
removing the dummy protective film from the display panel; and
bending the display panel in the bending area so that the pad area overlaps the display area,
wherein the dummy protective film is formed at a position corresponding to the pad area and is exposed to light to facilitate removal of the dummy protective film from the display panel.

12. The method of manufacturing a display device of claim 11, wherein
the protective film and the dummy protective film have a same thickness as each other,
the protective film includes a protective film base and a first adhesive layer sequentially laminated on the carrier film,
the dummy protective film includes a dummy protective film base and a dummy adhesive layer sequentially laminated on the carrier film, and
the dummy adhesive layer further includes a photoinitiator.

13. The method of manufacturing a display device of claim 12, wherein
the dummy adhesive layer includes the photoinitiator in an amount of at least 0.1 wt % and not more than 5 wt %.

14. The method of manufacturing a display device of claim 11, wherein,
in preparing the protective film member, the protective film is removed from an area corresponding to the bending area.

15. The method of manufacturing a display device of claim 12, wherein,
in preparing the protective film member, a spacer is formed on the dummy adhesive layer, wherein the spacer includes a spacer base and a second adhesive layer.

16. The method of manufacturing a display device of claim 15, wherein
a sum of a thickness of the dummy protective film and a thickness of the spacer is equal to a thickness of the protective film, and
a thickness of the spacer base is formed to be about 60% or less of a thickness of the protective film base.

17. The method of manufacturing a display device of claim 16, wherein
the dummy protective film is separated from the spacer upon exposure to light.

18. The method of manufacturing a display device of claim 11, wherein
the protective film has a thickness of about 100 μm to about 130 μm,
wherein the protective film includes a protective film base and a first adhesive layer, and a thickness of the first adhesive layer is formed to be about 10% to about 20% of a thickness of the protective film base.

19. The method of manufacturing a display device of claim 11, wherein
the display area includes a first display area, second display areas, and third display areas, wherein the first display area is a flat area, wherein the second display areas are located at edges of the first display area, and the third display areas are located between the second display areas, and
the second display areas have a single-curved surface shape and the third display areas have a double-curved surface shape.

20. An electronic device comprising:
a display device;
a processor;
a memory having stored application programs for execution by the processor,
wherein the display device comprises:
a display panel including a display area, a pad area, and a bending area, wherein the pad area is located adjacent to a first side of the display area, and the bending area is disposed between the display area and the pad area;
a protective film attached to a lower surface of the display panel and including a protective film base and an adhesive layer; and
a cover layer located below the protective film,
wherein the pad area is positioned on the cover layer in an overlapping arrangement with the display area due to bending of the bending area, and
the protective film has a thickness of about 100 μm to about 130 μm, and a thickness of the adhesive layer is about 10% to about 20% of a thickness of the protective film base; and
a user interface configured to sense user input via touch or cursor select of an icon presented on the display panel, wherein the processor is caused to execute one or more of the stored application programs upon receipt of the user input.
